(19) United States
(12) Patent Application Publication
(10) Pub. No.: US 2013/0176545 A1
(43) Pub. Date: Jul. 11, 2013

(54) PROJECTION EXPOSURE APPARATUS

(71) Applicants: Dirk Heinrich Ehm, Lauchheim (DE); Stefan-Wolfgang Schmid, Aalen (DE); Oliver Dier, Lauchheim (DE)

(72) Inventors: Dirk Heinrich Ehm, Lauchheim (DE); Stefan-Wolfgang Schmid, Aalen (DE); Oliver Dier, Lauchheim (DE)

(73) Assignee: Carl Zeiss SMT GmbH, Oberkochen (DE)

(21) Appl. No.: 13/760,243

(22) Filed: Feb. 6, 2013

Related U.S. Application Data
(63) Continuation of application No. PCT/EP2011/064796, filed on Aug. 29, 2011.

(30) Foreign Application Priority Data
Aug. 30, 2010 (DE) 102010039930.2

(51) Int. Cl. G03F 7/20

(52) U.S. Cl. CPC G03F 7/70191
USPC 355/67

(57) ABSTRACT

A projection exposure apparatus for semiconductor lithography includes optical elements, wherein at least one of the optical elements includes a mechanism for contactlessly producing electric currents in the optical element to heat the at least one optical element at least in regions.

### CROSS-REFERENCE TO RELATED APPLICATIONS

The present application is a continuation of, and claims benefit under 35 USC 120 to, international application PCT/EP2011/064796, filed Aug. 29, 2011, which claims benefit under 35 USC 119 of German Application No. DE 10 2010 039 930.2, filed Aug. 30, 2010. The entire disclosure of each of these applications is incorporated by reference herein.

### FIELD

The disclosure relates to a projection exposure apparatus for semiconductor lithography, in particular an EUV projection exposure apparatus which includes a heatable optical element.

### BACKGROUND

With the trend toward the ever further miniaturization of the components in semiconductor technology, it has become desirable for the wavelengths of the light used in projection exposure apparatuses also to be shortened further and further in order to be able to correspondingly increase the resolution capability of the projection objectives used. The wavelengths of the optical radiation used have recently been shortened as far as the EUV (Extreme UltraViolet) range. In such wavelength ranges, there are virtually no longer any optical components available which can produce imaging via diffraction, that is to say light refraction. Instead, in the EUV wavelength range, it is desirable to achieve imaging via reflection or via reflective elements. For this purpose, it is known to use mirrors whose surface properties are optimized towards the desired optical effect for use in a projection objective of a projection exposure apparatus, that is to say grazing incidence mirrors or multilayer mirrors, for example.

However, optical radiation of quite considerable power density has to be applied to the mirrors in order to achieve satisfactory imaging. In this case, a considerable proportion of the optical radiation is absorbed in the mirror material, which leads to heating of the mirror. An additional factor is that the illumination of the mirrors is not uniform depending on the structure to be imaged, but rather has considerable intensity gradients across the mirror area depending on the application. These intensity gradients stem from the fact that, for different structures to be produced on a wafer to be exposed, different illumination distributions are also used on the mask to be imaged. In this case, reference is also made to different illumination settings. For example, one typical illumination setting has two intensity maxima of the illumination radiation on the mask; reference is also made to a dipole setting in this context. Other settings are also conceivable. As a result, the inhomogeneous illumination of the mirrors used in the projection objective, on account of the illumination settings respectively chosen, have the effect that the mirrors are heated locally to different extents. On account of the thermal expansion of the mirror material, the resultant temperature gradient produces deformations of the mirrors, which ultimately lead to an impairment of the imaging quality. In order to counteract this effect, various solutions have been proposed in the past which were intended to be used to achieve a homogeneous temperature distribution across the mirror material.

For example, one possibility uses optical radiation introduced in a targeted manner, with wavelengths that are significantly different from the optical radiation used for imaging, in order to heat the respective optical element in regions in a targeted manner. However this can involve aligning the radiation exactly with the desired regions and keeping the region between the radiation source and the regions to be heated free of disturbing elements that could impair the incidence on the optical element. Moreover, in this case there is also the problem that, if appropriate, regions which are not intended to be heated are unintentionally heated on account of stray light, for example, which constitutes a further source error.

### SUMMARY

The disclosure provides a projection exposure apparatus in which targeted heating in regions can be achieved.

A projection exposure apparatus according to the disclosure for semiconductor lithography includes optical elements, wherein at least one of the optical elements has a mechanism for contactlessly producing electric currents in the optical element. The electric currents are suitable for heating the at least one optical element at least in regions. In other words, in the optical element which is intended to be temperature-regulated, local electric currents such as eddy currents, for example, are produced in a targeted manner. Due to the ohmic resistance of the material of the optical element, the eddy currents lead to local heating and thus ultimately to a homogenization of the temperature distribution across the optical element. The undesired deformations of the optical element as discussed in the introduction and the imaging errors associated therewith are effectively avoided as a result. By virtue of the fact that, unlike known conventional practice , the heating does not arise as a result of the incidence of radiation from outside, but rather arises directly in the material of the optical element itself, the above-described problems with regard to undesired heating of other elements or else shading are effectively avoided.

By virtue of the fact that the electric currents are produced contactlessly, that is to say without mechanical contact, in the optical element, minimal mechanical stressing of the optical element on account of the introduction of the currents is achieved.

In some embodiments, induction coils are used to contactlessly produce the electric currents. A plurality of specimens of the induction coils can be arranged in a spatially distributed manner in the region of the optical element, such that the alternating magnetic fields produced by the induction coils can act on specific regions of the optical element. Operation of the induction coils with an AC current having a frequency in the range of 25 to 50 Hz constitutes an advantageous choice of the operating parameters of the coils. The low frequency chosen is advantageous in particular because it is sufficiently far apart from the mechanical natural frequency usually possessed by optical elements in projection exposure apparatuses.

Alternatively, the induction coils can also be operated in a frequency range of a few kHz. In this case, too, it is advantageous, however, to choose a frequency range which is far enough away from the mechanical natural frequencies of the optical elements used.

Particularly in the case of an application of the disclosure in projection exposure apparatuses for EUV semiconductor lithography, the optical elements can be reflective optical elements, in particular grazing incidence mirrors or multilayer mirrors. A grazing incidence mirror should be understood hereinafter to mean a mirror having a metallic reflective surface. During operation of such a mirror in the short-wave spectral range, the reflectivity of the mirror becomes higher towards shallow angles of incidence (grazing incidence). In contrast thereto, multilayer mirrors are not based on reflection at a mirroring metallic layer, but rather on the fact that incident electromagnetic radiation is reflected from a spatially extended structure having a refractive index that varies periodically in one direction. The periodic structure mentioned is produced, in particular, by a multilayer region being applied to a substrate. The multilayer region can be, in particular, an alternating succession of silicon and molybdenum layers.

The reflective optical element can have a substrate and a reflective region arranged thereon. The mechanism for contactlessly producing temporally variable currents can be arranged, in particular, on the side of the substrate of the reflective optical element. Since the optical radiation used for exposure is applied to the reflective optical element usually from the side provided with the reflective region, the arrangement of the mechanism for contactlessly producing the temporally variable currents on the substrate side constitutes that variant in which the presence of the mechanism impairs the optical functionality of the optical element, that is to say of the mirror in the present case, the least.

In one simple embodiment of the disclosure, one or a plurality of induction coils is or are arranged on the substrate side of a multilayer mirror. The alternating magnetic field produces, in the multilayer region of the mirror, in particular in the molybdenum layers, electric eddy currents that already cause a certain heating of the mirror on account of the ohmic resistance of the layers mentioned.

In this case, a resistivity in the range of 10⁻⁶ ohm*cm to 10⁻⁵ ohm*cm can be assumed in the multilayer region.

It is therefore also possible to provide unmodified multilayer mirrors, for the purpose of heating, with the mechanism for contactlessly producing electric currents, that is to say with induction coils, for example. This variant allows, for example, the retrofitting of projection exposure apparatuses that are already in the field, that is to say in industrial use.

An improvement in the efficiency of the heating can be achieved, in particular, by virtue of the fact that a ferromagnetic material is situated between the multilayer region of the multilayer mirror and the substrate. In this case, the ferromagnetic material can be embodied as a layer having a thickness of less than 100 nm, preferably less than 50 nm, particularly preferably less than 5 nm. The ferromagnetic material can be arranged as a layer having a uniform thickness in the entire region between the multilayer region and the substrate. Alternatively, it is also possible for the ferromagnetic material not to be arranged over the whole area between the multilayer region and the substrate; in other words, island-like regions of ferromagnetic material can also be present between the multilayer region and the substrate whereas in other regions the substrate and the multilayer region are in direct contact, if appropriate in contact mediated by a metallic adhesion promoter layer. In this case, the embodiment of individual regions of ferromagnetic material between substrate and multilayer region has the effect that the optical element can be heated in specific regions in a targeted manner. The heating of the optical element is supported by the good thermal conductivity of the multilayer region.

In one variant of the disclosure, the layer of ferromagnetic material is formed with a thickness in the range of one to a plurality of μm; in this case, solely a—desired—thermally induced change in the thickness of the layer can make a considerable contribution also to a correction of the surface geometry of a multilayer mirror.

If appropriate, the layer of ferromagnetic material can be provided with smoothing or polishing layers in order to adapt the roughness to the desired properties of the multilayer mirror. The smoothing layers here can be a few nm thick, and polishing layers a few um thick. The ferromagnetic layer itself can also be embodied such that it can be polished.

In order to improve the adhesion of the ferromagnetic layer to the adjacent layers, it is furthermore possible to employ an adhesion promotion layer, e.g. using metal oxide, in particular aluminium oxide or zirconium oxide, or a metal such as Cr or Ti; this layer, which can also be embodied as a layer system, can have e.g. a thickness between 20 nm and 200 nm.

By way of example, a polishing layer can consist of amorphous silicon, microcrystalline silicon, silicon carbide, silicon nitride, titanium nitride, aluminium oxide, zirconium dioxide, chromium and/or mixtures thereof or include one or more of the aforementioned materials.

The polishing layer can have a thickness of 1 μm to 10 μm, preferably of 3 μm to 6 μm.

Using local variations e.g. with regard to thickness, magnetic properties or else composition of the ferromagnetic layer, it is possible to set desired temperature distributions in the multilayer mirror. Alternatively or additionally, a specific temperature distribution can also be set by way of the spatial arrangement of the mechanism for contactlessly producing electric currents.

Moreover, the ferromagnetic material can also be arranged between a reflective region of a grazing incidence mirror and the substrate thereof.

Furthermore, the ferromagnetic material need not necessarily be arranged exclusively between the multilayer region and the substrate of the multilayer mirror. As an alternative or in addition to an arrangement between the multilayer region and the mirror substrate, it is likewise conceivable to provide regions outside the intermediate region between substrate and multilayer layer on the multilayer mirror with the ferromagnetic material; in particular, the edge regions of the optical element come into consideration here. The same correspondingly applies to an application for grazing incidence mirrors.

The ferromagnetic material can contain, in particular, a substance from the group Co, Fe, Ni, CrO₂, Gd, Dy, EuO or Ho.

A further advantageous variant of the disclosure consists in the fact that at least one layer of the multilayer region of the multilayer mirror contains a ferromagnetic material. An advantageous double effect can thereby be achieved in that firstly the layer of the multilayer region contributes firstly to the optical effect, namely to the reflectivity of the multilayer mirror, and secondly supports the heating of the mirror by, for example, an alternating magnetic field incident from the rear side of the mirror. In particular, in the case of a construction of the multilayer region composed of two types of layers, one type of layer can completely contain the ferromagnetic material.

In order to avoid disturbing magnetostrictive effects, e.g. operation of the mechanism for contactlessly producing electric currents can be limited to times in which no exposure is effected. Likewise, by virtue of the frequency of an alternating field used being significantly higher than the operating frequency of a light source used for projecting, it is possible to achieve the effect that satisfactory imaging properties are maintained using averaging effects.

### BRIEF DESCRIPTION OF THE DRAWINGS

The disclosure is explained in greater detail below with reference to the figures, in which:

FIG. 1 shows an EUV projection exposure apparatus in which the disclosure is realized in one of the mirrors;

FIG. 2 shows a variant of the disclosure, wherein a homogeneous layer of ferromagnetic material is situated between the multilayer region and the substrate of a multilayer mirror;

FIG. 3 shows an embodiment of the disclosure, wherein the layer of ferromagnetic material is formed inhomogeneously between the multilayer region and the substrate;

FIG. 4 shows a further variant, wherein one type of the multilayers of the multilayer region contains ferromagnetic material; and

FIG. 5 shows a further embodiment of the disclosure, wherein ferromagnetic material is situated outside the region between substrate and multilayer region of a multilayer mirror.

### DETAILED DESCRIPTION

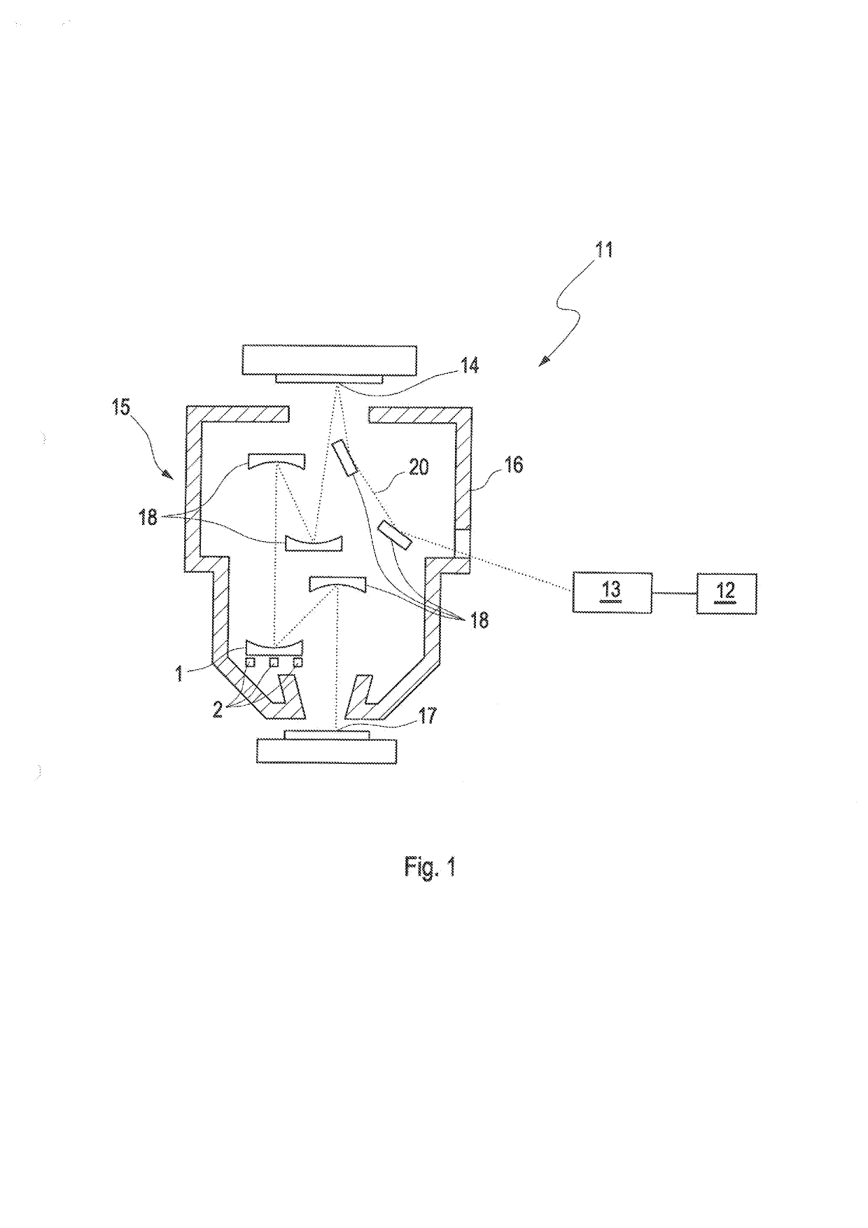

FIG. 1 illustrates purely schematically an EUV projection exposure apparatus 11, wherein the concept according to the disclosure is realized. The projection exposure apparatus 11 exhibits a light source 12, an EUV illumination system 13 for illuminating a field in an object plane 14, in which a structure-bearing mask is arranged, and also a projection objective 15 having a housing 16 and a radiation beam 20 for imaging the structure-bearing mask in the object plane 14 onto a light-sensitive substrate 17 for the production of semiconductor components. The projection objective 15 has optical elements embodied as mirrors 18 for the purpose of beam shaping. The illumination system 13 also has such optical elements for beam shaping or beam guiding. However, the latter are not illustrated in greater detail in FIG. 1.

It is readily discernable from FIG. 1 that the mirror 1 is equipped according to the disclosure with a mechanism for contactlessly producing electric currents 2, with induction coils in the present case. It is also conceivable to provide further mirrors 18 with a mechanism for contactlessly producing electric currents.

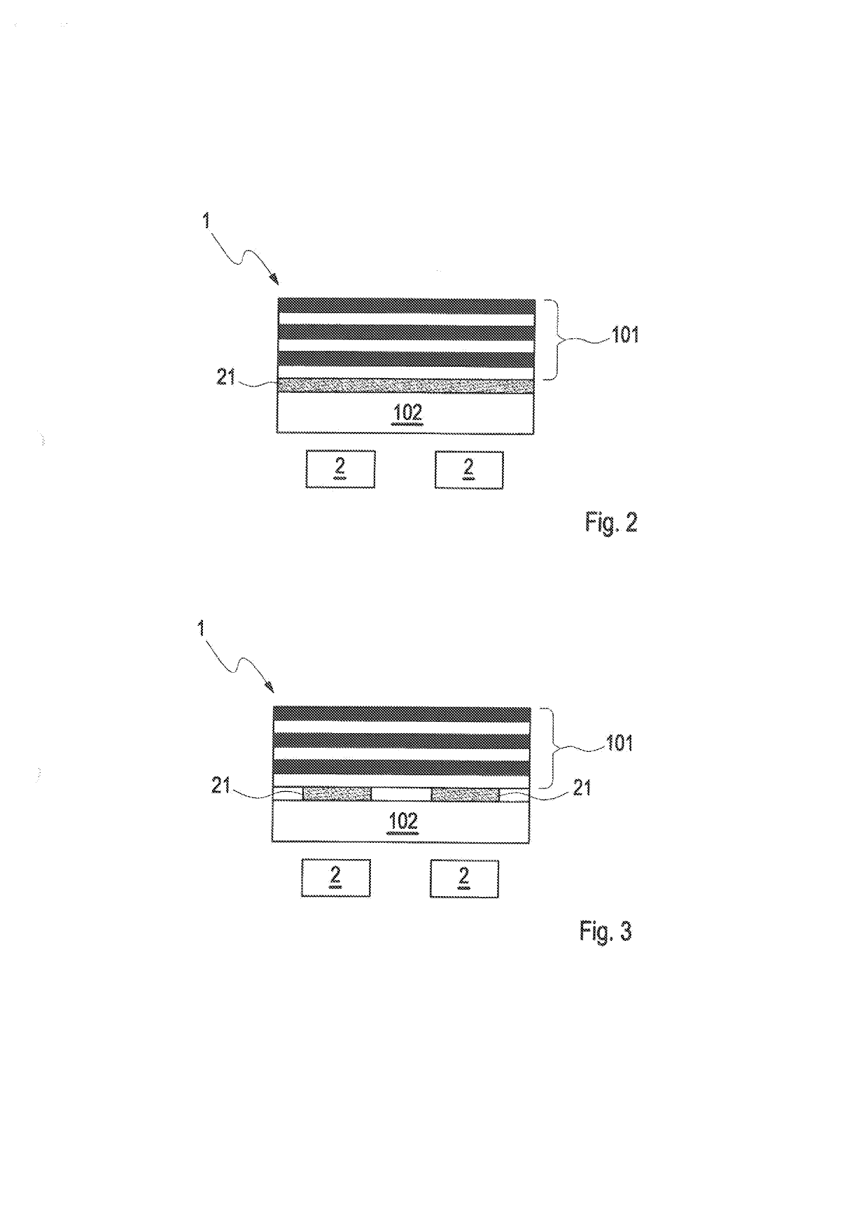

FIG. 2 shows a first embodiment of the disclosure, wherein the optical element is embodied as a multilayer mirror 1. In this case, the multilayer mirror 1 exhibits the substrate 102 and the multilayer region 101 arranged thereon. The substrate 102 can be, in particular, a material having a low coefficient of thermal expansion, such as, for example, Zero-dur or ULE. It serves for mechanically stabilizing the multilayer mirror 1. The multilayer region 101 is arranged on the substrate 102, the multilayer region having alternately changing material layers, for example in each case silicon and molybdenum in alternation. Only three of the aforementioned layers in each case are shown in the present example; in reality, approximately 30 to 100 of the layers are arranged on the multilayer mirror 1. A layer of ferromagnetic material 21 is arranged between the multilayer region 101 and the substrate 102. In the ferromagnetic material, currents, in particular eddy currents can be produced particularly effectively via temporally variable magnetic fields. One or a plurality of the materials Co, Fe, Ni, CrO₂, Gd, Dy, EuO or Ho is or are appropriate for the ferromagnetic material. On the substrate side of the multilayer mirror 1, the two coils 2 are arranged as a mechanism for contactlessly producing electric currents in particular in the ferromagnetic material 21. During operation, an AC voltage in the range of approximately 25 to 50 Hz is applied to the coils 2, as a result of which a temporally variable magnetic field arises, which extends right into the region of the ferromagnetic material 21. On account of the alternating magnetic field, currents are induced in the ferromagnetic material 21, which currents, on account of the ohmic resistance of the ferromagnetic material 21, lead to the heating thereof and heating of the surrounding regions in the multilayer mirror 1. The abovementioned choice of the frequency of the AC voltage has the advantage that a sufficiently large separation from the mechanical natural frequencies of the surrounding components, in particular of the mirror 1, is thereby ensured, such that excitation of mechanical oscillations on account of the temporally variable field is effectively avoided.

As already mentioned, a high-frequency AC voltage can also be used as long as a sufficient separation from the mechanical natural frequency of the components used is ensured.

On account of the thermal expansion, a local density and thus thickness variation further arises within the material 21 and also adjoining, likewise heated regions of the multilayer mirror 1, as a result of which a correction of the surface form of the multilayer mirror 1 can be achieved. The surface form of the mirror 1 is thus actively driveable. When driving the coils 2 for setting a desired local temperature variation, however, it should be taken into consideration that the mirror 1 is also heated by the impinging imaging light. This can be compensated for by measuring the imaging aberrations, that is to say the wavefront aberrations, for example, during the operation of the projection exposure apparatus and generating therefrom a control signal for driving the coils 2. This has the additional advantage that imaging aberrations which only occur during the operation of the projection objective can be corrected. In the case of catadioptric projection objectives, for example, wavefront aberrations arise on account of the heating of lens elements. When the imaging light passes through refractive elements, part of the radiation is always absorbed as well and leads to local heating of the elements, which can in turn lead to a certain deformation of the surface. Such imaging aberrations that arise during operation can also be compensated for by the mirror 1 according to the disclosure with active driving of the surface form.

In this case, it can be advantageous to provide further intermediate layers for example for stabilization and adhesion promotion. Furthermore, by way of example, in all embodiments, it is also possible to arrange an additional intermediate layer between the material 21 and the multilayer region 101, in order to achieve the desired smoothness. By way of example, polyimide layers can be used for this purpose. Alternatively or supplementarily, it is also possible to provide an additional intermediate layer below the multilayer region 101, which layer can be polished particularly well. Thus, by way of example, the actual surface form can be set particularly well.

In this case, the change in the geometry of the multilayer mirror 1 need not necessarily be reversible. Given a suitable choice of material, it is likewise conceivable, e.g. for the correction of manufacturing faults or deformations produced during operation, to perform an irreversible density and thus thickness change by inductive heating of a suitable material layer as a correction measure directly after the production of the multilayer mirror 1 or else after a certain operating duration.

FIG. 3 shows a variant of the disclosure, wherein, given an otherwise practically identical construction from FIG. 2, the region with the ferromagnetic material 21 is not embodied in a continuous fashion. The ferromagnetic material 21 is arranged in a manner distributed in an island-like fashion in the region between the multilayer region 101 and the substrate 102. This arrangement has the effect that the heating of the optical element 1 on account of the alternating magnetic field acting thereon takes place primarily in those regions of the optical element 1 which are adjacent to the ferromagnetic material 21. In the example shown in FIG. 3, it is thus possible, in particular, to compensate for greatly location-dependent temperature distributions in the multilayer region 101.

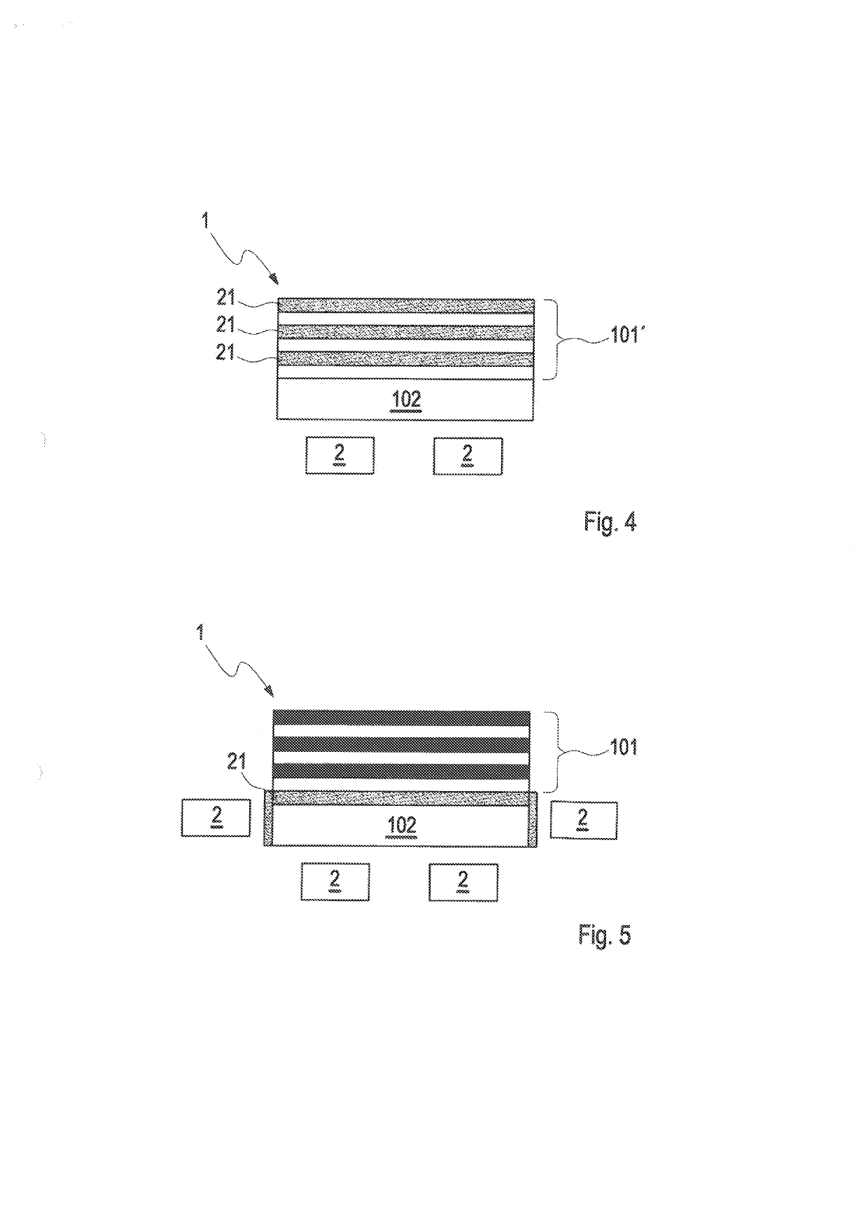

FIG. 4 shows an embodiment of the disclosure, wherein the multilayer region 101′ is embodied in such a way that one type of the layers consists of ferromagnetic material 21 or is provided with ferromagnetic material 21. The additional layer of ferromagnetic material 21, as shown in FIGS. 2 and 3, can thus be obviated; the action of the alternating magnetic field of the coil 2 produces the desired heating directly in the multilayer region 101′ of the multilayer mirror 1. In particular, the substances already mentioned from the group Co, Fe, Ni, CrO₂, Gd, Dy, EuO or Ho have proved to be advantageous materials for those layers which are provided with the ferromagnetic material.

FIG. 5 shows a variant of the disclosure, wherein ferromagnetic material 21 is also situated outside the region between the multilayer layer 101 and the substrate 102. As shown in FIG. 5, additional regions of the ferromagnetic material 21 are arranged at the side areas of the substrate 102; adjacent to the side areas, additional induction coils 2 are fitted, as a result of which it is possible to achieve particularly fast and large-area heating of the mirror substrate and thus of the multilayer mirror 1. Variants are also conceivable wherein the ferromagnetic material 21 is situated exclusively at the side areas of the multilayer mirror 1, such that the layer of ferromagnetic material 21 between substrate 102 and multilayer region 101 could be obviated; in this case, however, the edge regions of the multilayer mirror 1 are preferably heated, which can likewise be advantageous for specific applications and specific illumination settings.

What is claimed is:

1. An apparatus, comprising:
a plurality of optical elements comprising a first optical element,
wherein the first optical element comprises a mechanism configured to contactlessly produce electric currents in the first optical element to heat regions of the first optical element, and the apparatus is a semiconductor lithography projection exposure apparatus.

2. The apparatus of claim 1, wherein the mechanism comprises induction coils.

3. The apparatus of claim 1, wherein the first optical element is a reflective optical element.

4. The apparatus of claim 1, wherein the first optical element is a grazing incidence mirror.

5. The apparatus of claim 1, wherein the first optical element is a multilayer mirror.

6. The apparatus of claim 1, wherein the first optical element is a reflective optical element comprising a substrate and a reflective region supported by the substrate.

7. The apparatus of claim 6, wherein the substrate is between the reflective region and the mechanism.

8. The apparatus of claim 7, wherein the mechanism is configured to produce temporally variable currents.

9. The apparatus of claim 6, wherein the mechanism is configured to produce temporally variable currents.

10. The apparatus of claim 6, wherein the reflective element is a grazing incidence mirror.

11. The apparatus of claim 6, wherein the reflective element is a grazing incidence mirror which comprises a ferromagnetic material between the reflective region and the substrate.

12. The apparatus of claim 6, wherein the reflective region comprises a multilayer region.

13. The apparatus of claim 6, wherein the reflective region comprises a multilayer region, and the reflective optical element further comprises a ferromagnetic material between the multilayer region and the substrate.

14. The apparatus of claim 6, wherein the reflective optical element further comprises a ferromagnetic material between the substrate and the reflective region, and the ferro-magnetic material comprises a layer of ferromagnetic material having a thickness of less than 100 nm.

15. The apparatus of claim 6, wherein the reflective optical element further comprises a ferromagnetic material, and the ferromagnetic material is not between the reflective region and the substrate.

16. The apparatus of claim 6, wherein the reflective optical element further comprises a ferromagnetic material, and the ferromagnetic material is outside a region between the substrate and the reflective region.

17. The apparatus of claim 6, wherein the reflective optical element further comprises a ferromagnetic material comprises a material selected from the group consisting of Co, Fe, Ni, CrO₂, Gd, Dy, EuO or Ho.

18. The apparatus of claim 6, wherein the reflective region comprises a multilayer region, and a layer of the multilayer region comprises a ferromagnetic material.

19. The apparatus of claim 1, wherein the apparatus comprises a projection objective, and the first optical element is in the projection objective.

20. An apparatus, comprising:
a plurality of mirrors comprising a first mirror,
wherein:
the first mirror comprises a substrate, a reflective region, and a mechanism configured to contactlessly produce electric currents in the first mirror to heat regions of the first mirror;
the substrate is between the mechanism and the reflective region;
the first mirror comprises a ferromagnetic material; and
the apparatus is a semiconductor lithography projection exposure apparatus.

21. An objective, comprising:
a plurality of optical elements comprising a first optical element,
wherein the first optical element comprises a mechanism configured to contactlessly produce electric currents in the first optical element to heat regions of the first optical element, and the objective is a semiconductor lithography projection objective.
